(19) United States
(12) Patent Application Publication
(10) Pub. No.: US 2006/0267221 A1
(43) Pub. Date: Nov. 30, 2006

(54) Integrated-circuit die having redundant signal pads and related integrated circuit, system, and method

(76) Inventors: Greg Lee Allen, Boise, ID (US); Randall Don Briggs, Boise, ID (US)

Correspondence Address: AGILENT TECHNOLOGIES INC., INTELLECTUAL PROPERTY ADMINISTRATION, M/S DU404, P.O. BOX 7599, LOVELAND, CO, 80537-0599, US

(21) Appl. No.: 11/139,248

(22) Filed: May 27, 2005

(51) Int. Cl. H01L 23/48

(52) U.S. Cl. 257/786

(57) ABSTRACT

An integrated-circuit die includes a number of signal paths, and includes a greater number of signal pads that are operable to be coupled to the signal paths. By including more signal pads than signal paths on the die, one can often repair a defect in the connection of a pad to, e.g., a pad of another die, by connecting a signal path to another, i.e., redundant, pad. And such repairing of a pad-connection defect can often increase the yield of the integrated circuits incorporating such a die and/or can extend the lifetime of such an integrated circuit.

### BACKGROUND

To reduce the size of today's electronic circuits, manufacturers have developed integrated circuits (ICs) that include interconnected IC dies. For example, such an IC may include a first die stacked atop a second die, where signal pads on a surface of the first die are respectively connected to corresponding signal pads on a surface of the second die. As long as the connection between interconnected pads is “good,” a signal can propagate via the interconnected pads between a circuit disposed on the first die and a circuit disposed on the second die.

But unfortunately, the connection between two pads on different integrated-circuit dies may have or develop a non-repairable defect that renders this connection incapable of allowing signal propagation. Such defects may reduce the production yield of the integrated circuits that incorporate the dies. Or, if a defect develops after shipment of an integrated circuit to a customer, the defect may cause a premature failure of the integrated circuit and the device in which it is installed.

FIG. 1 is an exploded isometric view with portions broken away of a conventional IC 10, which includes two joined IC dies 12 and 14 disposed in a package 16. The dies 12 and 14 may be joined together with an adhesive or in another manner.

The die 12 includes signal pads 18, which, ideally, are each connected to a respective pad 20 of the die 14 such that signals can propagate between the dies via the pads 18 and 20. That is, ideally, the pads 18 and 20 are interconnected such that a first signal can propagate between the dies 12 and 14 via the pads 18a and 20a, a second signal can propagate between the dies via the pads 18b and 20b, and so on. The type of connection between a pair of corresponding pads 18 and 20 (e.g., pads 18a and 20a) depends on the signal type. For electrical signals, an electrically conductive pad 18 may merely contact a corresponding electrically conductive pad 20, or may be bonded to the pad 20 with an electrically conductive material such as solder or epoxy. For optical signals, an optically conductive pad 18 may merely contact a corresponding optically conductive pad 20, or may be bonded to the pad 20 with an optically conductive material.

But the connection between a pair of corresponding pads 18 and 20 may have or may develop a defect that renders the IC 10 inoperable. For example, the pair of corresponding pads 18a and 20a may be so badly misaligned during the manufacturing process that a signal cannot propagate between them. Or, even where the pads 18a and 20a are sufficiently aligned, the level of contact between them may be insufficient to allow signal propagation. This insufficient level of contact between the pads 18a and 20a may be the result of the manufacturing process, or may develop over time as the result of thermal stresses that cause the dies 12 and 14, and thus the pads 18a and 20a, to pull or shear apart.

Unfortunately, because it is impractical to impossible to repair a defect in the connection between a pair of corresponding pads 18 and 20 once the dies 12 and 14 are joined, if such a defect occurs before the IC 10 is shipped to a customer, then the manufacturer typically discards the IC, thus reducing the overall production yield for this IC.

Similarly, if such a connection defect develops after the IC 10 is shipped to a customer, then the customer typically replaces the IC, thus increasing the downtime of the system (not shown in FIG. 1) in which the IC is installed, and also increasing the cost and time required to maintain the system. In a more severe situation, the defect may render the entire system unrepairable.

### SUMMARY

An embodiment of the invention is an IC die that includes a number of signal paths and a greater number of signal pads that are operable to be coupled to the signal paths.

By including more signal pads than signal paths on the die, one can often effectively repair a defect in the connection between a pad and, e.g., a pad of another die, by connecting a signal path to another, i.e., redundant, pad. And such repairing of a pad-connection defect may increase the yield of the ICs incorporating such a die, and/or extend the operating lifetime of such an IC.

### BRIEF DESCRIPTION OF THE DRAWINGS

Advantages of embodiments of this invention will become more readily appreciated as the same become better understood by reference to the following detailed description in conjunction with the accompanying drawings.

FIG. 1 is an exploded isometric view with portions broken away of a conventional multi-die IC.

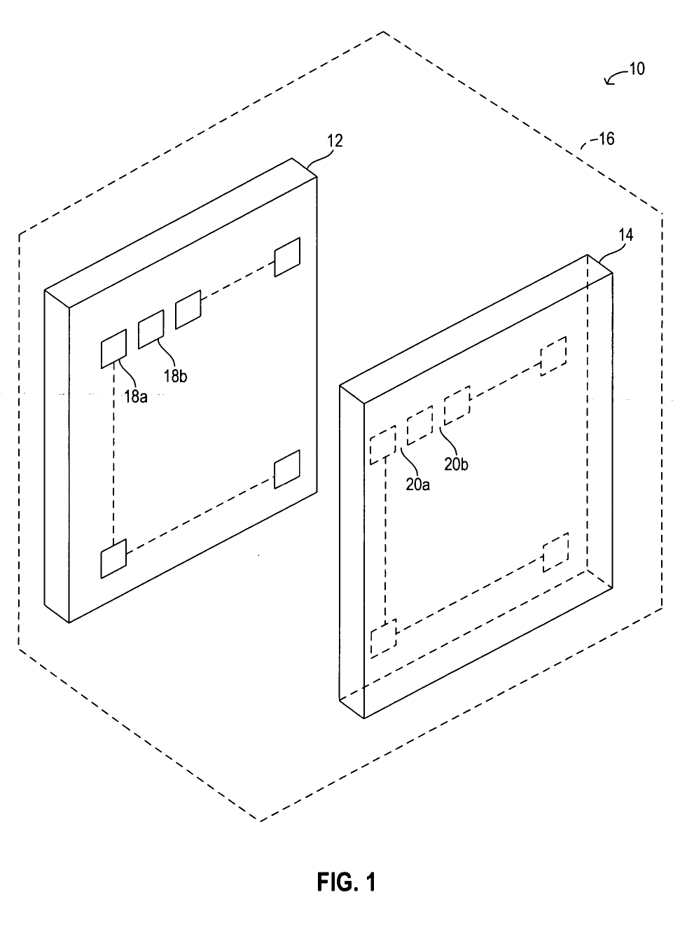

FIG. 2 is a cutaway side view of a signal interface between two dies of an IC according to an embodiment of the invention.

FIG. 3 is a combination of a cutaway side view of a signal interface between two dies of an IC and a schematic diagram of control and multiplexing circuitry disposed on the dies according to another embodiment of the invention.

FIG. 4 is a combination of a cutaway side view of a signal interface between two dies of an IC and a schematic diagram of control and multiplexing circuitry disposed on the dies according to another embodiment of the invention.

FIG. 5A is a schematic diagram of a controller disposed on one of the dies in FIG. 4 according to an embodiment of the invention.

FIG. 5B is a schematic diagram of a controller disposed on the other one of the dies in FIG. 4 according to an embodiment of the invention.

FIG. 6 is a diagram of a computer system that incorporates one or more of the ICs in FIGS. 2, 3, or 4 according to an embodiment of the invention.

### DETAILED DESCRIPTION

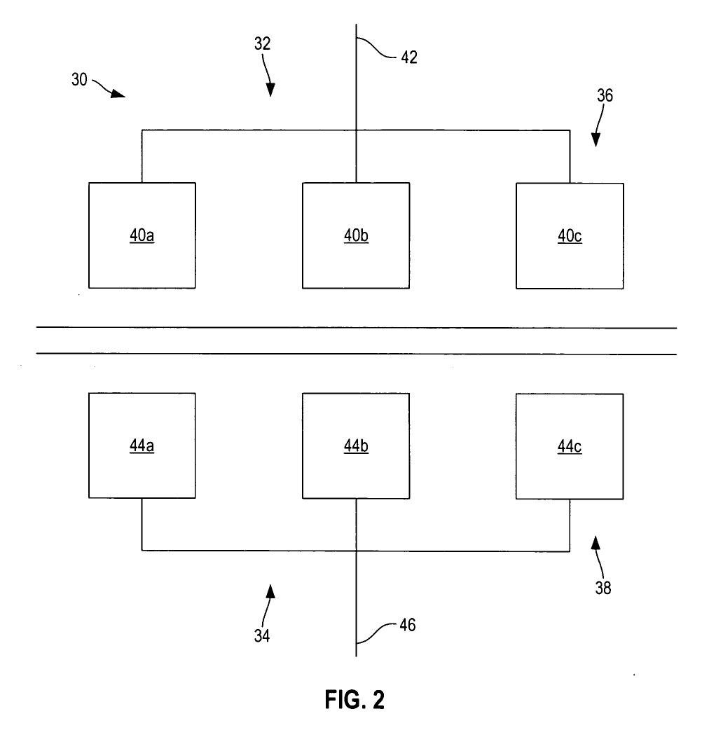

FIG. 2 is a cutaway side view of an IC 30 having first and second joined dies 32 and 34, which include redundant signal pads according to an embodiment of the invention. Specifically, the die 32 includes a group 36 of pads 40 and a signal path 42 having at least one redundant pad 40; likewise, the die 34 includes a group 38 of pads 44 and a signal path 46 having at least one redundant pad 44. As discussed below, these redundant pads often increase the yield and/or lifetime of the IC 30 by allowing a signal to propagate between the dies 32 and 34 even where there is a defect in the connection between a pair of corresponding pads 40 and 44, such as pairs 40a and 44a or 40c and 44c.

More specifically, the pad/path group 36 of the die 32 includes three signal pads 40a-40c and one signal path 42, which is connected to all three of the signal pads 40. Because the group 36 includes two more pads 40 than signal paths 42, the group includes two redundant pads per signal path.

Likewise, the pad/path group 38 of the die 34 includes three signal pads 44a-44c and one signal path 46, which is connected to all three of the signal pads 44. Therefore, like the group 36, the group 38 includes two redundant pads 44 per signal path 46.

During manufacture of the integrated circuit 30, the dies 32 and 34 are conventionally joined together such that ideally, the signal pads 40a-40c are each connected to a corresponding one of the pads 44a-44c. These ideal connections allow a signal to propagate between the signal paths 42 and 46 via each and every pair of corresponding pads. For example, if the signal is an electrical signal, then the pads 40 and 44 and the paths 42 and 46 are metal or another conductive material. Ideally, the pads 40a-40c each contact a corresponding one of the pads 44a-44c—for clarity of illustration, the pads 40a-40c are shown separated from the pads 44a-44c—such that the electrical signal can propagate between the paths 42 and 46 via the pair of corresponding pads 40a and 44a, the pair of pads 40b and 44b, and the pair of pads 40c and 44c. Alternatively, if the signal is an optical signal, then the pads 40 and 44 and the paths 42 and 46 are glass or another optical material. Ideally, the pads 40a-40c are each in optical alignment with a corresponding one of the pads 42a-42c such that the optical signal can propagate between the paths 42 and 46 via the pair of pads 40a and 44a, the pair of pads 40b and 44b, and the pair of pads 40c and 44c.

But even if the connections between as many as two pairs of corresponding pads 40 and 44 are defective or develop defects after manufacture, the redundant pads 40 and 44 still allow a signal to propagate between the paths 42 and 46. For example, if the connections between the pads 40a and 44a and 40b and 44b are defective, a signal can still propagate between the paths 42 and 46 via the pads 40c and 44c.

Therefore, because the redundant pads 40 and 44 can allow the IC 30 to operate even when the connection between a pair of corresponding pads is defective, the redundant pads can reduce the failure rate, and thus can increase the yield and lifetime, of the IC.

Still referring to FIG. 2, alternative embodiments of the IC 30 are contemplated. For example, although described as each including three pads 40 and 44 per signal path 42 and 46, the pad/path groups 36 and 38 may each include two pads or more than three pads per signal path. Furthermore, one group 36 may include a different number of pads 40 than another group 36; likewise, one group 38 may include a different number of pads than another group 38. In addition, although described as being on facing die surfaces and being in direct contact with one and other, the pads 40 and 44 may be on non-facing die surfaces, and may be interconnected by, e.g., wires or optical fibers.

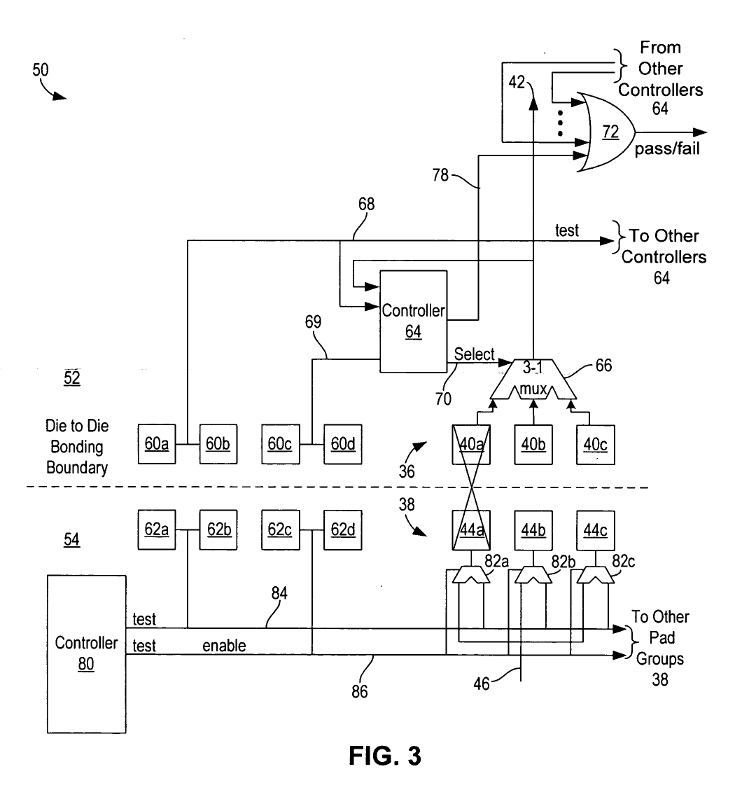

FIG. 3 is a combination cutaway side view and schematic diagram of a portion of an IC 50 having first and second joined dies 52 and 54, which, like the IC 30 of FIG. 2, include redundant signal pads 40 and 44 according to an embodiment of the invention. One difference between the IC 50 and the IC 30 is that to reduce the coupling capacitance between the signal paths 42 and 46 at the interface where the dies 52 and 54 are joined, circuitry on the dies allows a signal to propagate between the signal paths via only a single pair of corresponding pads 40 and 44.

As discussed above in conjunction with FIG. 2 for the IC 30, the pad/path group 36 of the die 52 includes three signal pads 40a-40c and one signal path 42, which is connected to all three of the pads; likewise, the pad/path group 38 of the die 54 includes three signal pads 44a-44c and one signal path 46, which is connected to all three of the pads 42. The dies 52 and 54 also respectively include pads 60a-60d and pads 62a-62d, which allow the propagation of pad-test and test-enable signals between the dies. During manufacture of the IC 50, the dies 52 and 54 are conventionally joined together such that ideally, the pads 40a-40c and 60a-60d are each coupled to a corresponding one of the pads 44a-44c and 62a-62d.

The die 52 also includes a controller 64, a three-input multiplexer 66, a test path 68, a test-enable path 69, a select bus 70, and a test-result logic gate 72. In response to a test signal received from the die 54 via the test path 68, the controller 64 identifies at least one pair of corresponding signal pads 40a-40c and 44a-44b that allows a signal to propagate between the signal paths 42 and 46, and generates on the bus 70 a select signal that causes the multiplexer 66 to select this identified pair for connecting the signal paths. The pads 60a-60d provide a redundant coupling of the test and test-enable paths 68 and 69 to the die 54. As long as at least one pair of corresponding pads 40a-40c and 44a-44c allows a signal to propagate between the signal paths 42 and 46, then the group 36 is operational, and thus the controller 64 generates on a signal path 78 a defective/operational signal having an “operational” level. Conversely, if none of the pairs of signal pads 40 and 42 allows a signal to propagate between the signal paths 42 and 46, then the group 36 is defective, and thus the controller 64 generates the defective/operational signal having a “defective” value. The test gate 72 generates a pass/fail signal that is the logical OR of the defective/operational signals from the control circuits 64 for each of the pad/path groups 36 on the die 52 (only one group 36 is shown in FIG. 3 for clarity). Therefore, if even one of the pad/path groups 36 is defective, then the pass/fail signal has a “fail” level, which indicates to, e.g., an external tester, that the IC 50 is defective and may not operate properly.

Similarly, the die 54 also includes a controller 80, multiplexers 82a-82c, a test path 84, and a test-enable path 86. In a pad-test mode of operation, the controller 80 generates a test-enable signal having a first level on the path 86, and this first level causes each of the multiplexers 82a-82c to couple a test signal on the path 84 to a corresponding pad 44a-44c. The pads 62a-62d provide a redundant coupling of the test and test-enable signal to the pads 60a-60d on the die 52. In a normal mode of operation, the controller 80 generates the test-enable signal having a second level, which disables the pad-test mode by causing each of the multiplexers 82a-82c to uncouple the test signal from each of the pads 44a-44c.

Still referring to FIG. 3, the operation of the IC 50 is discussed according to an embodiment of the invention where the connection between the pair of corresponding pads 40a and 44a is defective (the defect is indicated with an “X” in FIG. 3). Furthermore, discussion of certain signals, such as clock signals, which may be involved in this mode of operation is omitted for clarity.

When power is applied to the IC 50, i.e., the IC is “turned on,” the controller circuit 80 enters the pad-test mode and generates the test-enable signal on the path 86. In response to the test-enable signal, the controller 64 also enters the test mode.

In response to the test-enable signal, the multiplexers 82a-82c respectively couple the test signal on the test path 84 to the corresponding pads 44a-44c. Also, the control circuit 64 generates on the select bus 70 a select value that causes the multiplexer 66 to couple the pad 40a to the signal path 42.

Next, the controller 80 generates the test signal having a first logic level, e.g., a logic 0, and the control circuit 64 compares the test signal (received on the test path 68 ) to the signal level on the path 42.

Because the connection between the first pair of corresponding pads 40a and 44a is defective, the signal level on the path 42 does not equal the level of the test signal; therefore, the control circuit 64 identifies this pad connection as defective.

Then, the controller 80 generates the test signal having a second logic level, e.g., logic 1. Although the control circuit 64 has already identified the connection between the pads 40a and 44a as defective, control circuits for the other pad/path groups (not shown in FIG. 3), which are similar to the pad/path groups 36 and 38, continue to test the connections between the first pair of corresponding pads in those groups.

Next, the control circuit 64 updates the select value to cause the multiplexer 66 to couple the pad 40b to the signal path 42.

Then, the controller 80 generates the test signal having the first and second logic levels, and the control circuit 64 compares the signal on the path 44 to the test signal as discussed above. Because the connection between the pads 40b and 44b is not defective, i.e., is “good”, the control circuit 64 maintains the select value in its current state such that the multiplexer 66 continues to couple the pad 40b to the signal path 42. The control circuit 64 also generates an “operational” level for the defective/operational signal on the path 78 to indicate that the groups 36 and 38 have at least one pair of corresponding pads (here the pads 40b and 44b) that can couple a signal between the paths 42 and 46.

Next, for the benefit of the other pad/path groups 36 and 38 (not shown in FIG. 3) having defective connections between the first and second pairs of corresponding pads, the controller 80 again generates the test signal having the first and second logic levels. But the control circuit 64 remains idle because it has already determined that the connection between the pads 40b and 44b is good.

Then, the controller 80 exits the pad-test mode by transitioning the test-enable signal to a level that cause the multiplexers 82a-82c to respectively couple the signal path 46 to the pads 44a-44c. But because the multiplexer 66 couples only the pad 40b to the signal path 42, a signal propagates between the signal paths 42 and 46 via the pair of corresponding pads 40b and 44b only.

If after the pad-test mode any of the control circuits 64 (only one shown in FIG. 3 for clarity) generate a “defective” level for the defective/operational signal, the gate 72 generates a “fail” level at its output, thus indicating to, e.g., external circuitry, that the IC 50 may be defective.

The above-described pad-test mode can execute during the manufacturer's pre-shipping testing, and/or can execute “in the field” whenever the system incorporating the IC 50 is powered on. Therefore, if a coupling defect arises “in the field” between a pair of corresponding pads 40 and 44, then the control circuit 64 and controller 80 can effectively repair this defect during the next power-up of the IC 50, as long as a pair of corresponding pads having a good connection is available to replace the pair having the defective connection.

After the controller 80 exits the pad-test mode, the IC 50 enters a normal operating mode during which a signal can propagate from the signal path 46 to the signal path 42 via the pads 40b and 44b—per above, the control circuit 64 selected these pads because the connection between the pads 40a and 44a is defective.

Still referring to FIG. 3, alternative embodiments similar to those contemplated above for the IC 30 of FIG. 2 are also contemplated for the IC 50. Furthermore, although shown as being unidirectional, the multiplexer 66 and the multiplexers 82a-82c may be bidirectional such that a signal can propagate from the path 42 to the path 46, and from the path 46 to the path 42, via the pair of corresponding pads 40 and 44 that the multiplexer 66 selects.

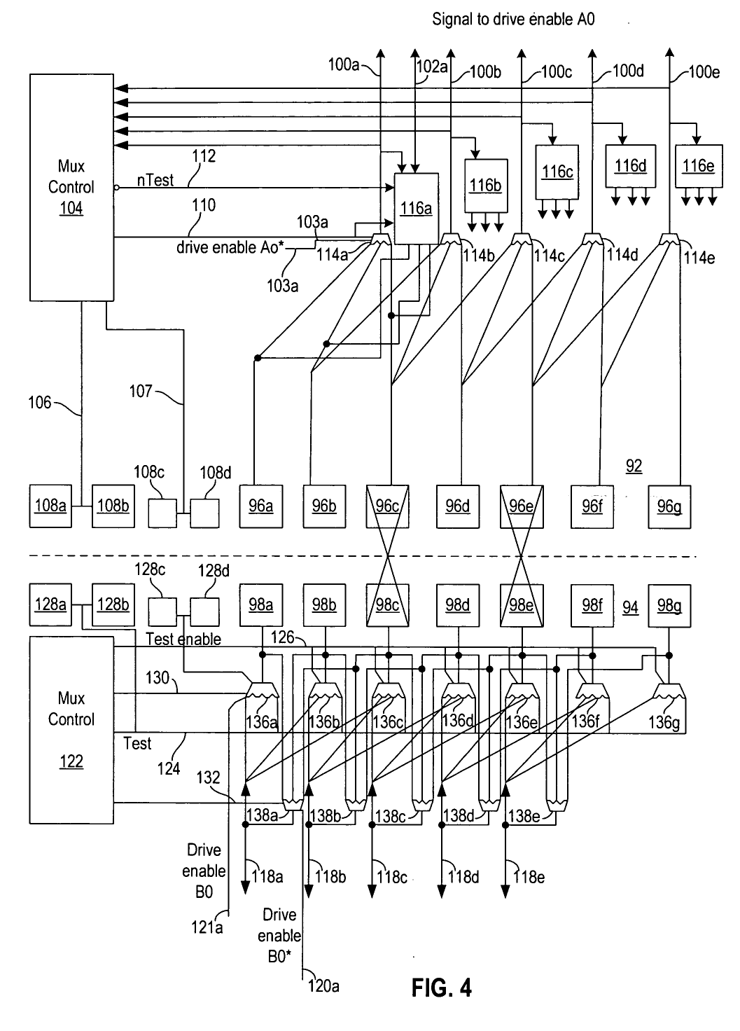

FIG. 4 is a combination cutaway side view and schematic diagram of a portion of an IC 90 having first and second joined dies 92 and 94, which include redundant signal pads 96 and 98, respectively, according to an embodiment of the invention. One difference between the IC 90 and the ICs 30 and 50 of FIGS. 2-3 is that instead of having one or more redundant pads for each signal path, each die 92 and 94 includes one or more redundant pads for groups of multiple signal paths. This technique often allows the IC 90 to implement pad redundancy with fewer pads per signal path as compared to the ICs 30 and 50. For example, the dies 32, 34, 52, and 54 of the ICs 30 and 50 each include three pads per signal path 42 and 46 respectively; but, as discussed below, the dies 92 and 94 of the IC 90 each include seven pads per five signal paths, i.e., 1.4 pads per signal path. Therefore, for the same number of signal paths, the IC 90 includes approximately half as many signal pads as the ICs 30 and 50.

In addition to the seven signal pads 96a-96g, the die 92 includes five bidirectional signal paths 100a-100e, five first-direction drive-enable paths 102 (only path 102 a shown for clarity), five second-direction drive-enable paths 103 (only path 103 a shown for clarity), a first controller 104, test-signal and test-enable paths 106 and 107 respectively coupled to pads 108a-108b and 108c-108d, a first select bus 110, multiplexers 114a-114e, and demultiplexers 116a-116e (for clarity, only demultiplexer 116a is shown fully connected). In response to a test signal received from the die 94 via the test-signal path 106, the first controller 104 identifies five pairs of the signal pads 96a-96g and 98a-98g that have good connections, and generates on the bus 110 a select value that causes the multiplexers 114a-114e and demultiplexers 116 to select these identified pairs of pads for connecting the signal paths. As long as at least five pair of corresponding signal pads 96a-96g and 98a-98g have good connections, then the IC 90 is operational (barring other defects not discussed). Furthermore, the multiplexers 114 and the demultiplexers 116 together allow bi-directional signal propagation between the signal paths 100a-100e and the die 94.

Similarly, in addition to the seven signal pads 98a-98g, the die 94 includes five bidirectional signal paths 118a-118e, five first-direction drive-enable paths 120 (only path 120 a shown for clarity), five second-direction drive-enable paths 121 (only path 121 a shown for clarity), a second controller 122, test-signal and test-enable paths 124 and 126 respectively coupled to pads 128a-128b and 128c-128d, second and third select busses 130 and 132, multiplexers 136a-136g, and multiplexers 138a-138e. As discussed further below, in a test mode of operation, the controller 122 generates on the path 126 a test-enable signal having a first level, and this first level causes each of the multiplexers 136a-136g to couple the test signal on the path 124 to a corresponding pad 98a-98g. In a normal mode of operation, the controller 122 generates the test-enable signal having a second level, which disables the test mode, causes the multiplexers 136a-136g and 138a-138e to couple the signal paths 118a-118e to selected ones of the pads 98a-98g. Together, the multiplexers 136 and 138 allow bidirectional signal propagation between the signal paths 118a-118e and the signal paths 100a-100e of the die 92.

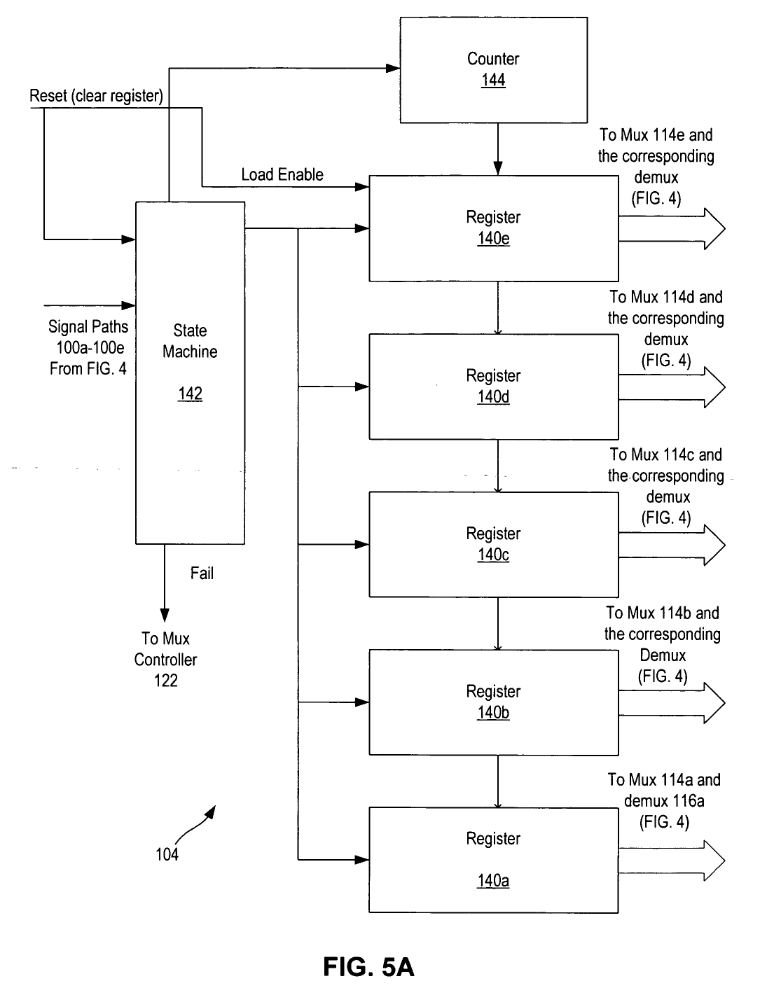

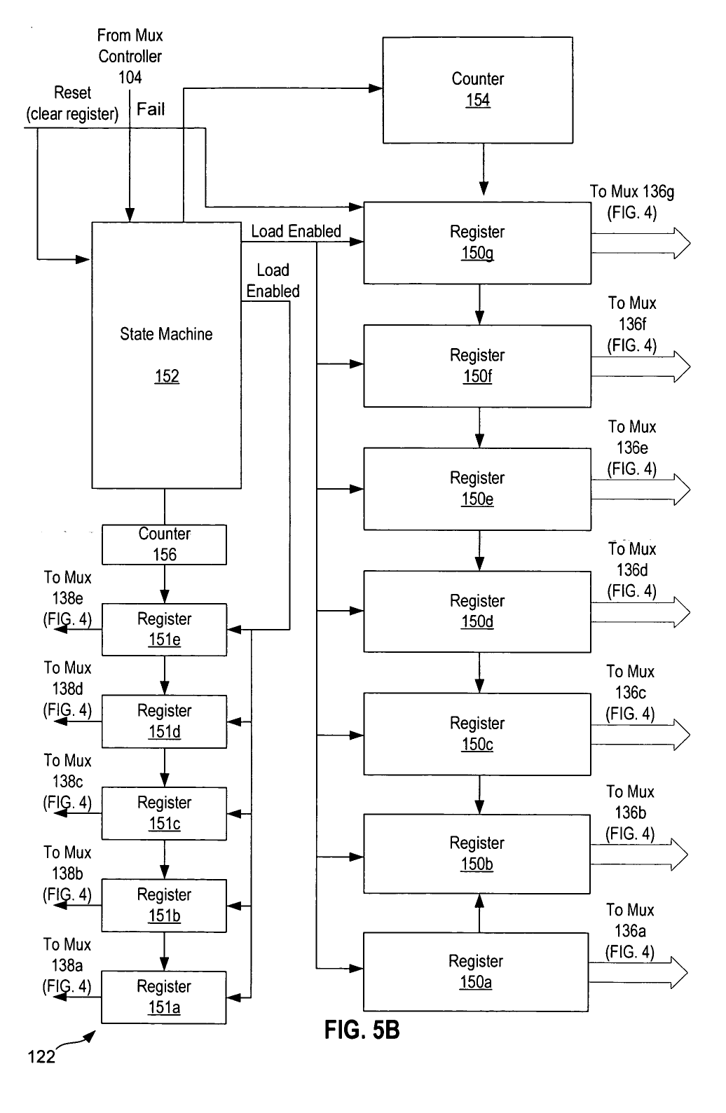

FIG. 5A is a schematic block diagram of the first controller 104 of FIG. 4 according to an embodiment of the invention. The controller 104 includes multiplexer-demultiplexer-select registers 140a-140e, a state machine 142 that is coupled to the signal paths 100a-100e and that generates a fail signal when it detects a defective connection between a pair of corresponding pads, and a defect counter 144. Although not shown in FIG. 4, the fail signal may be coupled to the die 94 (FIG. 4) via a signal path and redundant pads in the same manner as the test and test-enable signals are coupled from the die 94 to the die 92. As discussed below, during a test mode, the state machine 142 causes the registers 140 to be loaded with the appropriate values for selecting the active inputs of the multiplexers 114 and the active outputs of the demultiplexers 116. For example, a 0 stored in the register 140 a enables the 0^{th} (leftmost) input of the multiplexer 114a and disables the remaining two inputs, and enables the 0^{th} output (leftmost) of the demultiplexer 116a and tri-states the remaining two outputs.

FIG. 5B is a schematic block diagram of the second controller 122 of FIG. 4 according to an embodiment of the invention. The controller 122 includes multiplexer-select registers 150a-150g and 151a-151e, a state machine 152 that receives the fail signal from the first controller 104 (FIGS. 4 and 5A), and defect counters 154 and 156. As discussed below, during a test mode, the state machine 152 causes the registers 150 and 151 to be loaded with the appropriate values for selecting the active inputs of the multiplexers 136 and 138, respectively.

Referring to FIGS. 4-5B, the operation of the IC 90 is discussed according to an embodiment of the invention where the respective connections between the pairs of corresponding pads 96c and 98c and 96e and 98e are defective (these defective connections are shown as “X” in FIG. 4). Furthermore, discussion of certain signals, such as clock signals, which may be involved in this mode of operation are omitted for clarity.

When power is applied to the IC 90, i.e., the IC is powered on, the controller 122 enters a pad-test mode, resets to 0 the contents of the registers 150 and 151 and the counters 154 and 156, and generates a test-enable signal on the path 126. In response to the test-enable signal, the controller 104 also enters the pad-test mode, resets to 0 the contents of the registers 140 and the counter 144 to enable the 0^{th} (i.e., the leftmost) inputs of the multipexers 114a-114e, and generates on the path 112a signal test, which disables the demultiplexers 116. Further in response to the test-enable signal, the multiplexers 136a-136g each couple via their fourth input (i.e., rightmost input) a test signal on the path 124 to a corresponding one of the pads 98a-98g.

Next, the controller 122 generates the test signal having a first logic level, e.g., a logic 0, and the control circuit 104 compares the test signal (received on the test path 106) to the signal level on the signal path 100a—this signal level propagates to the path 100a via the pads 96a and 98aand the 0^{th} input of the multiplexer 114a.

Because the connection between the pads 96a and 98ais good, the signal level on the path 100a equals the level of the test signal; therefore, the control circuit 104 identifies this connection as good for the first logic level.

Then, the controller 122 generates the test signal having a second logic level, e.g., a logic 1, and the control circuit 104 compares the test signal to the signal level on the signal path 100a.

Because the connection between the pads 96a and 98ais good, the signal level on the path 100a equals the level of the test signal; therefore, the control circuits 104 and 122 identify this connection as good for the second logic level, and thus identify this connection as being good overall. Specifically, the controller 104 generates the fail signal having a pass level; in response, the counter 144 maintains its contents of 0, and shifts its previous contents of zero into the register 140e. Also in response to the pass level, the counters 154 and 156 maintain their contents of 0, and shift their previous contents of 0 into the registers 150g and 151e, respectively.

Next, the controller 122 generates the test signal having the first and second logic levels as described above, and the control circuit 104 compares these test-signal levels to the signal levels received by the signal path 100b via the pads 96b and 98b and the 0^{th} input of the multiplexer 114b. Because the connection between the pads 96b and 98b is good, the control circuits 104 and 122 identify this connection as being good. Specifically, the controller 104 generates the fail signal having a pass level; in response, the counter 144 maintains its contents of 0, and shifts its previous contents of 0 into the register 140e, which shifts its previous contents of 0 into the register 140d. Also in response to the pass level, the counters 154 and 156 maintain their contents of 0, and shift their previous contents of 0 into the registers 150g and 151e, which respectively shift their previous contents of 0 into the registers 150f and 151d.

Then, the controller 122 generates the test signal having the first and second logic levels as described above, and the control circuit 104 compares these test-signal levels to the signal levels received by the signal path 100c via the pads 96c and 98c and the 0^{th} input of the multiplexer 114c. Because the connection between the pads 96c and 98c is bad, the control circuits 104 and 122 identify this connection as being defective. Specifically, the controller 104 generates the fail signal having a fail level; in response, the counter 144 increments its contents to 1, but does not shift any value into the register 140e. Similarly, the counter 156 increments its contents to 1, but does not shift any value into the register 151e. But in addition to incrementing its contents to 1, the counter 154 shifts a 1 into the register 150g, which shifts its previous contents of 0 into the register 150f, which shifts its previous contents of 0 into the register 150e.

Next, the controller 122 generates the test signal having the first and second logic levels as described above, and the control circuit 104 compares these test-signal levels to the signal levels received by the signal path 100d via the pads 96d and 98d and the 0^{th} input of the multiplexer 114d. Because the connection between the pads 96d and 98d is good, the control circuits 104 and 122 identify this connection as being good. Specifically, the controller 104 generates the fail signal having a pass level; in response, the counter 144 maintains its contents at 1, and shifts its previous contents of 1 into the register 140e, which shifts its previous logic contents of logic 0 into the register 140d, which shifts its previous contents of logic 0 into the register 140c. Similarly, the counter 156 maintains its contents at 1, and shifts its previous contents of 1 into the register 151e, which shifts its previous contents of 0 into the register 151d, which shifts its previous contents of 0 into the register 151c. Also in response to the pass level, the counter 154 maintains its contents at 1, and shifts its previous contents of 1 into the register 150g, which shifts its previous contents of 1 into the register 150f, which shifts its previous contents of 0 into the register 150e, which shifts its previous contents of 0 into the register 150d.

Then, the controller 122 generates the test signal having the first and second logic levels as described above, and the control circuit 104 compares these test-signal levels to the signal levels received by the signal path 100e via the pads 96e and 98e and the 0^{th} input of the multiplexer 114e. Because the connection between the pads 96e and 98e is bad, the control circuits 104 and 122 identify this connection as being defective. Specifically, the controller 104 generates the fail signal having a fail level; in response, the counter 144 increments its contents to 2. Because the multiplexer 114e is the last multiplexer in the group of multiplexers 114, the state machine 142 twice shifts a 2 from the counter 144 into the register 140e, which shifts its previous contents into the register 140d, and so on. This insures that all of the registers 140a-140d are loaded with appropriate values. Similarly, the counter 156 increments its contents to 2, and the state machine 152 twice shifts a 2 from the counter 156 into the register 151e, which shifts its previous contents into the register 151d, and so on, so that all of the registers 151a-151e are loaded with appropriate values. Also in response to the fail level, the counter 154 increments its contents to 2, and the state machine 152 three times shifts a 2 into the register 150g, which shifts its previous contents into the register 150f, and so on, so that all of the registers 150a-150g are loaded with appropriate values.

The controller 122 then transitions the test-enable signal to a disable level, and exits the test mode. In response to the disable level of the test-enable signal, the controller 104 also exits the test mode.

Table I shows the values stored in each register 140a-140e, 150a-150g, and 151a-151e for this example after the test mode.

TABLE I

| Registers | Contents | Registers | Contents |
|---|---|---|---|
| 140a & 151a | 0 | 150a | 0 |
| 140b & 151b | 0 | 150b | 0 |
| 140c & 151c | 1 | 150c | 1 |
| 140d & 151d | 2 | 150d | 1 |
| 140e & 151e | 2 | 150e | 2 |
| | | 150f | 2 |
| | | 150g | 2 |

Consequently, per Table I, the signal paths 100a and 118a are interconnected via the pads 96a and 98a, signal paths 100b and 118b are interconnected via the pads 96b and 98b, signal paths 100c and 118c are interconnected via the pads 96d and 98d, signal paths 100d and 118d are interconnected via the pads 96f and 98f, and signal paths 100e and 118e are interconnected via the pads 96g and 98g.

Still referring to FIGS. 4-5B, the operation of the IC 90 in a normal (non-test) mode is discussed according to an embodiment of the invention where the contents of the registers 140a-140e, 150a-150g, and 151a-151e are as shown in Table I.

To send a signal from the path 118a on the die 94 to the path 100a on the die 92, circuitry (not shown in FIGS. 4-5B) on the die 94 transitions the signal drive_enable_b0 on the path 121a to an active level and the signal drive_enable_b0* on the path 120a to an inactive level; this enables the multiplexer 136a and disables the multiplexer 138a. Next, this circuitry generates the signal on the path 118a. Because the registers 140a and 150a both store 0, the signal propagates from the path 118a to the path 100a via the 0^{th} input of the multiplexer 138a, the pads 96a and 98a, and the 0^{th} input of the multiplexer 114a—the multiplexer 114a is enabled and the demultiplexer 116a is disabled because the signal is drive_enable_A0 and drive_enable_A0* on paths 102a and 103a have their default in active and active levels, respectively.

Circuitry (not shown in FIGS. 4-5B) on the die 94 sends signals from the paths 118b-118e to the paths 100b-100ea, respectively, in a similar manner.

Similarly, to send a signal from the path 100a on the die 92 to the path 118a on the die 94, circuitry (not shown in FIGS. 4-5B) on the die 92 transitions the signal drive_enable_a0 on the path 102a to an active level and the signal drive_enable_a0* on the path 103a to an inactive level; this enables the demultiplexer 116a and disables the multiplexer 114a. Next, this circuitry generates the signal on the path 100a. Because the registers 140a and 150a both store 0, the signal propagates from the path 100a to the path 118a via the 0^{th} output of the demultiplexer 116a, the pads 96a and 98a, and the 0^{th} input of the multiplexer 138a—the multiplexer 138a is enabled and the multiplexer 136a is disabled because the signals drive_enable_B0 and drive_enable_B0* on paths 121a and 120a have their default inactive and active levels respectively.

Circuitry (not shown in FIGS. 4-5B) on the die 92 sends signals from the paths 100b-100e to the paths 118b-118e, respectively, in a similar manner.

Still referring to FIGS. 4-5B, alternative embodiments similar to those contemplated above for the IC 30 of FIG. 2 and IC 50 of FIG. 3 are also contemplated for the IC 90. Furthermore, although specific multiplexer, demultiplexer, and controller circuitry is described, any other type of circuitry may be used to connect the signal paths 100 and 118 via good pairs of corresponding pads 96 and 98. In addition, although in the described embodiment the ratio of pads to signal paths is 1.4, any other ratio that is greater than 1 may be implemented. Moreover, the pad-redundancy techniques discussed in conjunction with the ICs 30, 50, and 90 may be combined on a single IC.

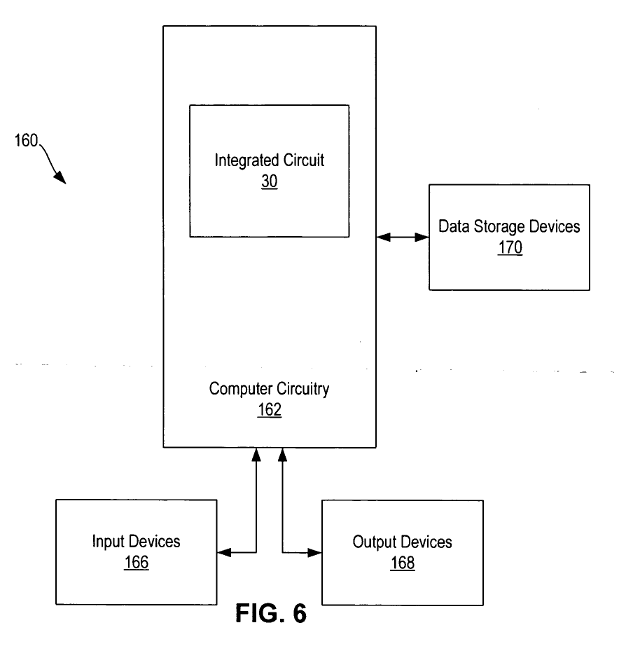

FIG. 6 is a block diagram of an electronic system 160, such as a computer system, that incorporates one or more of the ICs 30, 50, and 90 of FIGS. 2-4 according to an embodiment of the invention. For clarity, however, the system 160 is shown incorporating only the IC 30 of FIG. 2. The system 160 includes computer circuitry 162, which includes the IC 30 and which performs computer functions, such as executing software to perform desired calculations and tasks. The circuitry 162 also typically includes a processor and a memory circuit (neither shown in FIG. 6), which is coupled to the processor. One or more input devices 166, such as a keyboard or a mouse, are coupled to the computer circuitry 162 and allow an operator (not shown) to manually input data thereto. One or more output devices 168 are coupled to the computer circuitry 162 to provide to the operator data generated by the computer circuitry 162. Examples of such output devices 168 include a printer and a video display unit. One or more data-storage devices 170 are coupled to the computer circuitry 162 to store data on or retrieve data from external storage media (not shown). Examples of the storage devices 170 and the corresponding storage media include drives that accept hard and floppy disks, tape cassettes, and compact disk read-only memories (CD-ROMs).

From the foregoing it will be appreciated that, although specific embodiments of the invention have been described herein for purposes of illustration, various modifications may be made without deviating from the spirit and scope of the invention.

What is claimed is:

1. An integrated-circuit die, comprising:
a first number of signal paths; and
a second number of signal pads that are operable to be coupled to the signal paths, the second number being greater than the first number.

2. An integrated circuit, comprising:
a first die, comprising,
a first number of first signal paths, and
a second number of first signal pads that are operable to be coupled to the signal paths, the second number being greater than the first number.

3. The integrated circuit of claim 2 wherein each of the signal paths is coupled to multiple ones of the signal pads.

4. The integrated circuit of claim 2 wherein the first die further comprises multiplexing circuitry operable to couple each of the signal paths to a respective one of the signal pads.

5. The integrated circuit of claim 2 wherein the first die further comprises:
a controller operable to identify as functional signal pads that are able to carry a signal; and
multiplexing circuitry operable to couple each of the signal paths to a respective functional signal pad.

6. The integrated circuit of claim 2 wherein:
the signal paths comprise electrically conductive paths; and
the signal pads comprise electrically conductive pads.

7. The integrated circuit of claim 2 wherein:
the signal paths comprise optically conductive paths; and
the signal pads comprise optically conductive pads.

8. The integrated circuit of claim 2, further comprising:
a second die comprising,
a third number of second signal paths, and
a fourth number of second signal pads that are operable to be coupled to the second signal paths, each of the second signal pads corresponding to a respective one of the first signal pads, the fourth number being greater than the third number.

9. The integrated circuit of claim 8 wherein:
the third number equals the first number; and
the fourth number equals the second number.

10. The integrated circuit of claim 8 wherein each of the second signal paths is coupled to multiple ones of the second signal pads.

11. The integrated circuit of claim 8 wherein the second die further comprises multiplexing circuitry operable to couple each of the second signal paths to a respective one of the second signal pads.

12. The integrated circuit of claim 8 wherein:
the first die further comprises,
a first control circuit operable to identify as functional first pads to which a signal can propagate from respective second pads of the second die, and
first multiplexing circuitry coupled to the first control circuit and operable to couple each first signal path to a respective functional first pad; and
the second die further comprises,
a second control circuit coupled to the first control circuit and operable to identify as functional each second pad that corresponds to a respective functional first pad, and
second multiplexing circuitry coupled to the second control circuit and operable to couple each second signal path to a respective functional second pad.

13. The integrated circuit of claim 8 wherein:
the first die further comprises,
a first control circuit operable to identify as functional first pads to which a signal can propagate from respective second pads of the second die, and
first multiplexing circuitry coupled to the first control circuit and operable to allow unidirectional signal propagation between each first signal path and a respective functional first pad; and
the second die further comprises,
a second control circuit coupled to the first control circuit and operable to identify as functional each second pad that corresponds to a respective functional first pad, and
second multiplexing circuitry coupled to the second control circuit and operable to allow unidirectional signal propagation between each second signal path and a respective functional second pad.

14. The integrated circuit of claim 8 wherein:
the first die further comprises,
a first control circuit operable to identify as functional first pads to which a signal can propagate from respective second pads of the second die, and
first multiplexing circuitry coupled to the first control circuit and operable to allow bidirectional signal propagation between each first signal path and a respective functional first pad; and
the second die further comprises,
a second control circuit coupled to the first control circuit and operable to identify as functional each second pad that corresponds to a respective functional first pad, and
second multiplexing circuitry coupled to the second control circuit and operable to allow bidirectional signal propagation between each second signal path and a respective functional second pad.

15. The integrated circuit of claim 8, further comprising:
a package; and
wherein the first and second dies are disposed within the package.

16. The integrated circuit of claim 8 wherein the first die is attached to the second die.

17. An electronic system, comprising:
an integrated circuit, comprising,
a die, comprising,
a first number of signal paths, and
a second number of signal pads that are operable to be coupled to the signal paths, the second number being greater than the first number.

18. A method, comprising:
determining whether a signal can propagate between a first signal pad on a first integrated-circuit die and a second signal pad on a second integrated-circuit die; and
respectively coupling the first and second signal pads to first and second signal paths that are respectively disposed on the first and second dies if the signal can propagate between the first and second signal pads.

19. The method of claim 18 wherein determining comprises determining whether the signal can propagate between the first and second signal pads when circuitry on at least one of the first and second integrated-circuit dies is reset.

20. The method of claim 18, further comprising respectively isolating the first and second signal pads from the first and second signal paths if a signal cannot propagate between the first and second signal pads.

21. The method of claim 18 wherein:
determining comprises determining whether the signal can propagate between the first and second signal pads when the signal has a first level and when the signal has a second level; and
coupling comprises respectively coupling the first and second signal pads to the first and second signal paths if the signal can propagate between the first and second signal pads when the signal has the first level and when the signal has the second level.
